(19) United States
(12) Patent Application Publication
(10) Pub. No.: US 2026/0148760 A1
(43) Pub. Date: May 28, 2026

(54) CURRENT OFFSET DETECTION AMPLIFIER CIRCUIT FOR PUF BASED ON MAGNETORESISTIVE RANDOM-ACCESS MEMORY, AND PUF DEVICE HAVING THE SAME

(71) Applicant: UIF (University Industry Foundation), Yonsei University, Seoul (KR)

(72) Inventors: SEONG-OOK JUNG, Seoul (KR); DONGHAN KO, Seoul (KR); DOYOON LIM, Seoul (KR); WANGYU LEE, Seoul (KR)

(21) Appl. No.: 19/397,850

(22) Filed: Nov. 21, 2025

(30) Foreign Application Priority Data
Nov. 26, 2024 (KR) 10-2024-0170560

(51) Int. Cl. G11C 11/16

(52) U.S. Cl. CPC G11C 11/1655; G11C 11/1659; G11C 11/1673; G11C 11/1695

(57) ABSTRACT

A current offset detection amplifier circuit comprises: a detection circuit configured to, in a precharge phase, detect and store a voltage difference corresponding to currents flowing through a pair of bit lines connected to two cells configured based on a resistive memory element and storing the same data, and to, in an amplification phase following the precharge phase, output a pair of detection signals having an amplified voltage difference according to currents flowing through a pair of bit lines cross-connected with the stored voltage difference; and a detection amplifier circuit configured to, in the precharge phase, store a voltage level corresponding to the pair of detection signals output from the detection circuit, and to, in the amplification phase, detect and amplify variations in the voltages of the pair of detection signals in a coupled manner, thereby outputting a pair of response signals.

### CROSS-REFERENCE TO RELATED APPLICATIONS

This application claims priority under 35 U.S.C. §119(a) to Korean Patent Application No. 10-2024-0170560, filed on November 26, 2024, with the Korean Intellectual Property Office, the disclosure of which is incorporated herein in its entirety by reference.

### BACKGROUND

### Technical Field

The present disclosure relates to a current offset detection amplifier circuit and a PUF device having the same, and more particularly, to a current offset detection amplifier circuit for a PUF based on a magnetoresistive random-access memory and a PUF device having the same.

### DESCRIPTION OF THE RELATED ART

PUF (Physically Unclonable Function) is a security technique that utilizes the characteristic that physical deviations, such as line delay and gate delay, exist in the manufactured circuit due to randomly occurring minute process variations even when the circuit is manufactured according to the same manufacturing process under the same design.

As a response, PUF devices can output an output key that is determined by physical variations occurring randomly during the manufacturing process, even when the same input is applied. Accordingly, as an output key, PUF devices utilize unique characteristics of the hardware itself, which are determined by manufacturing process conditions and cannot be predicted even by the circuit designer, thereby providing a high level of security against various external attacks. In addition, unlike conventional security devices, PUF devices do not require a separate Non-Volatile Memory (hereinafter referred to as “NVM”) for storing encryption keys, thereby achieving advantages of low power consumption, low cost, and a small chip area.

Meanwhile, conventional PUF devices have mainly been fabricated based on CMOS transistors. However, since CMOS transistors exhibit large variations in threshold voltage (Vₜₕ) not only due to manufacturing process variations but also due to changes in temperature and voltage, there is a problem wherein the response may vary depending on environmental conditions. In other words, environmental changes can result in abnormal responses.

In this regard, research has been actively conducted to enable PUF devices to robustly output responses according to their unique characteristics even under environmental changes, by employing resistive memory elements such as Magnetoresistive Random-Access Memory (hereinafter referred to as “MRAM”). In PUF devices configured based on resistive memory elements, a response is generated by using a signal difference detected among memory cells having the same data state (for example, data “0”). In an ideal case, memory cells having the same state should output signals of the same level; however, in practice, signals of different levels are output due to differing inherent characteristics caused by process variations during manufacturing. Accordingly, the PUF device generates a response by detecting differences in signal levels resulting from such different inherent characteristics.

However, since the signal difference detected among memory cells having the same data state is very small, there is a problem in that the response may change even due to a slight detection error. Therefore, a technique is required to prevent detection errors caused by factors such as leakage currents in unselected rows, bit line (BL) parasitic resistance, and offsets in detection circuits.

### SUMMARY OF THE INVENTION

An object of the present disclosure is to provide a current offset detection amplifier circuit and a PUF device having the same, which can obtain an accurate response by eliminating the influence of leakage current, parasitic resistance, and offset.

According to an embodiment of the present disclosure, a current offset detection amplifier circuit comprises: a detection circuit configured to, in a precharge phase, detect and store a voltage difference corresponding to currents flowing through a pair of bit lines connected to two cells configured based on a resistive memory element and storing the same data, and to, in an amplification phase following the precharge phase, output a pair of detection signals having an amplified voltage difference according to currents flowing through a pair of bit lines cross-connected with the stored voltage difference; and a detection amplifier circuit configured to, in the precharge phase, store a voltage level corresponding to the pair of detection signals output from the detection circuit, and to, in the amplification phase, detect and amplify variations in the voltages of the pair of detection signals in a coupled manner, thereby outputting a pair of response signals.

The detection circuit may comprise: a control switch circuit configured to connect the pair of bit lines to first and second nodes during the precharge phase, and to cross-connect the pair of bit lines to the first and second nodes during the amplification phase; first and second NMOS transistors connected between the first and second nodes and a pair of detection output nodes from which the pair of detection signals are output, the gates of the first and second NMOS transistors being commonly applied with a clamp voltage; a stacked PMOS circuit comprising first and second stack circuits, each stack circuit comprising a plurality of PMOS transistors connected in series between the power supply voltage and the pair of detection output nodes; and a first capacitor connected between the gates of the plurality of PMOS transistors in the first stack circuit and the gates of the plurality of PMOS transistors in the second stack circuit.

The detection circuit may further comprise a first gate connection switch configured to connect a first detection output node of the pair of detection output nodes to the gates of the plurality of PMOS transistors in the first stack circuit during the precharge phase, and a second gate connection switch configured to connect a second detection output node of the pair of detection output nodes to the gates of the plurality of PMOS transistors in the second stack circuit during the precharge phase.

The control switch circuit may comprise a first switch circuit configured to connect a bit line of the pair of bit lines to the first node during the precharge phase and to connect a bit line bar of the pair of bit lines to the first node during the amplification phase, and a second switch circuit configured to connect the bit line bar to the second node during the precharge phase and to connect the bit line to the second node during the amplification phase.

The detection amplifier circuit may comprise a first stacked inverter circuit configured to detect and amplify a voltage variation of a detection signal among the pair of detection signals and output an inverted response signal of the pair of response signals, and a second stacked inverter circuit configured to detect and amplify a voltage variation of an inverted detection signal among the pair of detection signals and output a response signal of the pair of response signals.

The first stacked inverter circuit may comprise a second capacitor connected between a first amplification input node to which the detection signal is applied and a first internal input node, a first internal inverter including a first internal PMOS transistor and a first internal NMOS transistor connected in series with their gates commonly connected to the first internal input node, and a first external inverter including a first external PMOS transistor and a first external NMOS transistor connected respectively between a supply voltage and the first internal PMOS transistor, and between the first internal NMOS transistor and a ground voltage, with their gates commonly connected to the first amplification input node.

The second stacked inverter circuit may comprise a third capacitor connected between a second amplification input node to which the inverted detection signal is applied and a second internal input node, a second internal inverter including a second internal PMOS transistor and a second internal NMOS transistor connected in series with their gates commonly connected to the second internal input node, and a second external inverter including a second external PMOS transistor and a second external NMOS transistor connected respectively between a supply voltage and the second internal PMOS transistor, and between the second internal NMOS transistor and a ground voltage, with their gates commonly connected to the second amplification input node.

The detection amplifier circuit may further comprise a first equalization transistor configured to connect the first internal input node and a first amplification output node, from which the inverted response signal is output, during the precharge phase, and a second equalization transistor configured to connect the second internal input node and a second amplification output node, from which the response signal is output.

The detection amplifier circuit may further comprise a first latch switch configured to connect the first internal input node and a second amplification output node, from which the response signal is output, during a latch phase following the amplification phase, and a second latch switch configured to connect the second internal input node and the first amplification output node, from which the inverted response signal is output, during the latch phase.

The current offset detection amplifier circuit may further comprise two offset-canceling switches configured to connect, in the precharge phase and the amplification phase, a first and a second detection output node, from which the pair of detection signals is output from the detection circuit, to a first and a second amplification input node of the detection amplifier circuit, respectively.

The cells may be implemented as STT-MRAM.

According to another embodiment of the present disclosure, a PUF device may comprise: a cell array including a plurality of cells defined by a plurality of word lines, a plurality of bit lines, and a plurality of source lines, the cells being configured based on resistive memory elements; a word line driver configured to select and activate at least one of the plurality of word lines; a bit line selector configured to select two bit lines as a pair from among the plurality of bit lines; a detection circuit configured to, when two cells storing the same data are selected by the activated word line and the selected bit line pair, detect and store a voltage difference corresponding to currents flowing through the two selected cells via the selected bit line pair during a precharge phase, and to output a pair of detection signals having an amplified voltage difference according to currents flowing through a bit line pair cross-connected with the stored voltage difference during an amplification phase following the precharge phase; and a detection amplifier circuit configured to store voltage levels corresponding to the pair of detection signals output from the detection circuit during the precharge phase, and to detect and amplify voltage variations of the pair of detection signals in a coupling manner during the amplification phase, thereby outputting a pair of response signals.

The current offset detection amplifier circuit and the PUF device having the same according to the present disclosure may have a two-stage structure comprising a detection circuit and a detection amplifier, wherein a voltage difference detected in a first stage is sensed and amplified in a coupling manner by a second stage, thereby obtaining an accurate response in which the influence of leakage current, parasitic resistance, and offset is suppressed.

### BRIEF DESCRIPTION OF THE DRAWINGS

FIG. 1 illustrates a schematic diagram of a PUF device according to an embodiment of the present disclosure.

FIG. 2 is a schematic diagram for explaining the detailed structure and operation of an STT-MRAM-based cell.

FIG. 3 illustrates the detailed structure of a current offset detection amplifier circuit of FIG. 1.

FIG. 4 is a timing diagram for explaining the operation of the current offset detection amplifier circuit of FIG. 3.

FIG. 5 is a schematic diagram for explaining a precharge operation of the current offset detection amplifier circuit of FIG. 3.

FIG. 6 is a schematic diagram for explaining an amplification operation of the current offset detection amplifier circuit of FIG. 3.

FIG. 7 is a schematic diagram for explaining a latch operation of the current offset detection amplifier circuit of FIG. 3.

### DETAILED DESCRIPTIONOF THE INVENTION

Hereinafter, specific embodiments of the present disclosure will be described with reference to the drawings. The following detailed description is provided to help with comprehensive understanding of a method, a device, and/or a system described in this specification. However, this is only an example, and the present invention is not limited thereto.

In describing embodiments of the present disclosure, when it is determined that detailed description of well-known technologies related to the present invention may unnecessarily obscure the gist of embodiments, the detailed description will be omitted. Terms to be described below are terms defined in consideration of functions in the present invention, and may vary depending on the intention, practice, or the like of a user or operator. Therefore, the terms should be defined on the basis of the overall content of this specification. Terms used in the detailed description are only used to describe embodiments and should not be construed as limiting. Unless otherwise clearly specified, a singular expression includes the plural meaning. In this description, an expression such as “include” or “have” is intended to indicate certain features, numerals, steps, operations, elements, or some or combinations thereof, and should not be construed as excluding the presence or possibility of one or more other features, numerals, steps, operations, elements, or some or combinations thereof. Also, the terms “unit,” “device,” “module,” “block,” and the like described in this specification refer to units for processing at least one function or operation, which may be implemented by hardware, software, or a combination of hardware and software.

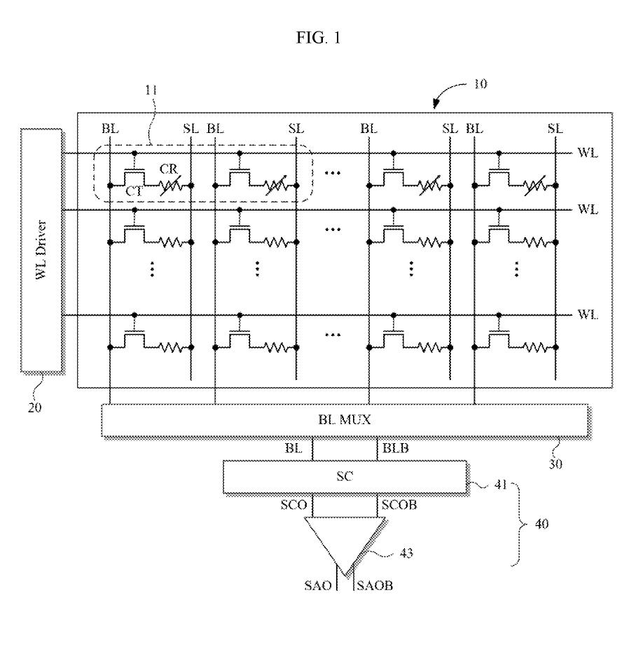

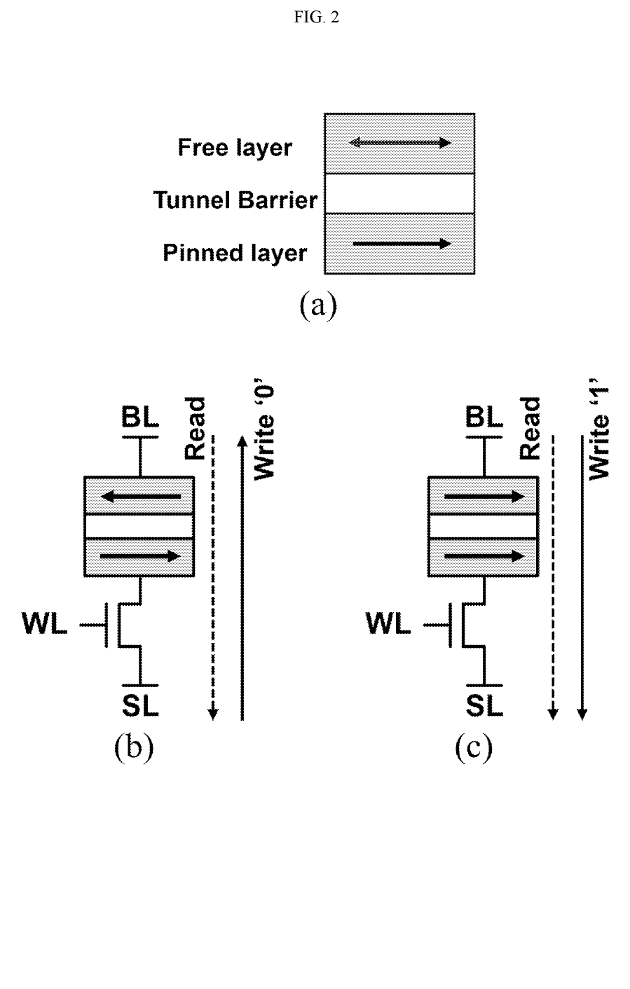

FIG. 1 illustrates a schematic diagram of a PUF device according to an embodiment, and FIG. 2 is a schematic diagram for explaining the detailed structure and operation of an STT-MRAM-based cell.

Referring to FIG. 1, the PUF device according to an embodiment may include a cell array 10, a word line driver 20, a bit line selector 30, and a current offset detection amplifier circuit 40.

The cell array 10 includes a plurality of cells defined by a plurality of word lines WL, a plurality of bit lines BL, and a plurality of source lines SL.

The plurality of word lines WL may be formed to extend in a first direction, for example, in a row direction, and the plurality of bit lines BL and the plurality of source lines SL may be formed to extend in a second direction, for example, in a column direction, in parallel with each other. That is, the plurality of word lines WL may be formed to intersect the plurality of bit lines BL and the plurality of source lines SL.

Each of the plurality of cells may be configured to include a cell transistor CT and a cell resistor CR. The cell transistor CT and the cell resistor CR are connected in series between a corresponding bit line BL and a corresponding source line SL among the plurality of bit lines BL and the plurality of source lines SL. A gate of the cell transistor CT is connected to a corresponding word line WL among the plurality of word lines WL. Accordingly, when the word line WL connected by the word line driver 20 is selected and activated, the cell transistor CT is turned on, thereby electrically connecting the bit line BL and the source line SL through the cell resistor CR.

In the PUF device according to an embodiment, each cell is configured as an MRAM including a resistive memory element. In particular, in the present embodiment, it is assumed that the cell is implemented as a Spin-Transfer Torque Magnetic Random-Access Memory (hereinafter referred to as “STT-MRAM”) that utilizes magnetic spin among various types of MRAM.

As shown in (a) of FIG. 2, in a cell implemented with STT-MRAM, the cell resistor CR has a structure in which a free layer, which is a magnetic layer, is arranged over a tunnel barrier, which is an insulator, on top of a pinned layer, which is a magnetic layer. In a cell of STT-MRAM having this structure of cell resistor CR, data is stored by controlling the direction of electron spins in the free layer according to the direction of the spin current during a write operation. For example, as shown in (b) of FIG. 2, when a spin current higher than the switching current flows from the source line SL to the bit line BL, that is, from the pinned layer to the free layer, and the spin directions of the pinned layer and the free layer are opposite, that is, in the AP (Anti-Parallel) state, the resistance value of the cell resistor CR increases, so that a data value of 0 can be stored. In contrast, as shown in (c) of FIG. 2, when a spin current higher than the switching current flows from the bit line BL to the source line SL, that is, from the free layer to the pinned layer, and thus the spin directions of the pinned layer and the free layer are the same, in the P (Parallel) state, the resistance value of the cell resistor CR decreases, so that a data value of 1 can be stored. The data values corresponding to each state may be assigned inversely depending on the configuration.

The read operation for the data stored in the cell resistor CR may be performed by allowing current to flow from the bit line BL toward the source line SL and sensing the signal level according to the resistance value of the cell resistor CR.

STT-MRAM is an improved version of MRAM, offering advantages such as low power consumption, fast read/write speeds, and non-volatility, which allows data to be retained even when power is turned off.

Meanwhile, the word line driver 20 selects and activates at least one word line WL from the plurality of word lines WL as designated by a controller (not shown). The bit line selector 30 selects a pair of bit lines BL from the plurality of bit lines BL as designated by the controller and connects them to the current offset detection amplifier circuit. Here, the word line driver 20 and the bit line selector 30 may select the word lines WL and bit lines BL, respectively, based on a row address and a column address applied to the controller.

Since the bit line selector 30 selects bit lines BL in pairs, the cells in the cell array 10 may also be selected in pairs. That is, the cells of the cell array 10 may always be selected as pairs, and the two cells that are selected together as a pair are referred to herein as a cell pair 11.

Selecting a cell pair 11 in the PUF device is intended to use one of the two cells in the cell pair 11 as a detection cell for obtaining a unique characteristic, and to use the other cell as a reference cell that serves as a comparison target for determining the unique characteristic of the detection cell. Here, the designation of the detection cell and the reference cell among the two cells of the cell pair 11 is merely a matter of configuration, and the detection cell and the reference cell may be interchanged.

However, the detection cell and the reference cell of the cell pair 11 must have the same state; that is, the same data must be stored in both cells. Accordingly, the two cells of the cell pair 11 may have identical data stored in advance.

Although FIG. 1 illustrates, as a simple example, that a cell pair 11 is selected from two cells connected to the same word line WL and to two adjacent bit lines BL, two cells that are spaced apart from each other may also be selected as the cell pair 11. That is, the two cells may be cells connected to bit lines BL that are not adjacent, or may be cells connected to different word lines WL. In some cases, two cells included in different cell arrays may also be selected as the cell pair 11.

For the sake of convenience in understanding, the bit line connected to the reference cell among the two bit lines BL selected as a pair by the bit line selector 30 is referred to as the bit line bar BLB, and the selected two bit lines BL are represented as a bit line pair BL and BLB.

The current offset detection amplifier circuit 40 detects and amplifies a voltage level difference corresponding to the resistance difference between the cell resistors CR of the detection cell and the reference cell through the bit line pair BL and BLB selected by the bit line selector 30, thereby generating a response. In particular, the current offset detection amplifier circuit 40 of one embodiment has a two-stage structure including a detection circuit 41 and a detection amplifier circuit 43, which not only increases sensing margin and gain but also suppresses the influence of offset caused by leakage current, parasitic resistance, and transistor characteristic variations, thereby preventing response errors.

The detection circuit 41 accurately detects a small resistance difference corresponding to the unique characteristics of the detection cell and the reference cell and performs a first-stage amplification to output a pair of detection signals SCO and SCOB. The detection amplifier circuit 43 then performs a second-stage detection amplification of the voltage difference between the pair of detection signals SCO and SCOB output from the detection circuit 41, thereby outputting a stable pair of response signals SAO and SAOB.

A detailed structure and operation of the current offset detection amplifier circuit 40 according to one embodiment will be described below.

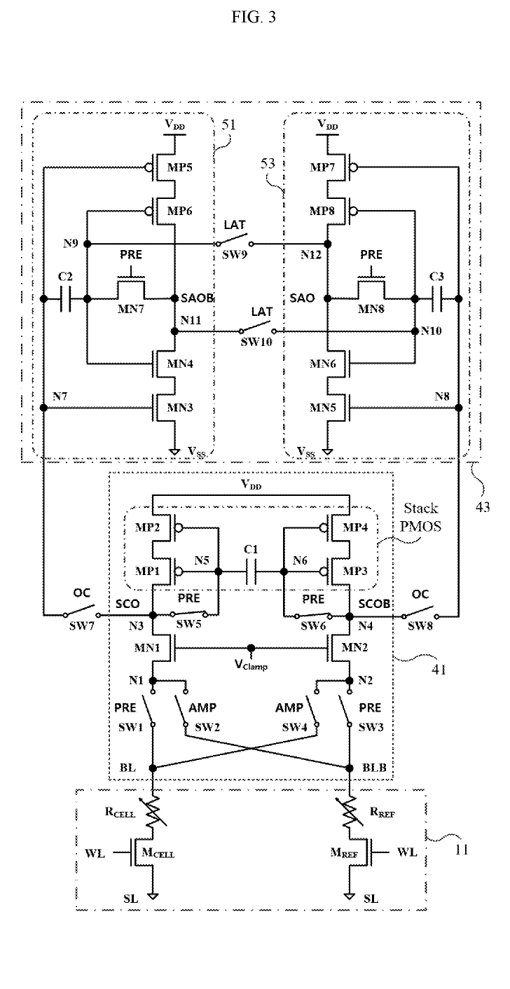

FIG. 3 illustrates the detailed structure of a current offset detection amplifier circuit of FIG. 1.

Referring to FIG. 3, in the current offset detection amplifier circuit 40, the detection circuit 41 includes: a control switch circuit connected between the bit line pair BL and BLB selected by the bit line selector 30 and first and second nodes N1 and N2; two NMOS transistors MN1 and MN2 connected between the first and second nodes N1 and N2 and a pair of detection output nodes N3 and N4 from which the pair of detection signals SCO and SCOB are output; a stacked PMOS circuit having a plurality of PMOS transistors MP1 and MP2, and MP3 and MP4, which are stacked and connected in series between the supply voltage V_{DD} and each of the pair of detection output nodes N3 and N4; a first capacitor C1 connected between the gates of the plurality of PMOS transistors MP1 and MP2, and MP3 and MP4 of the stacked PMOS circuit; and two gate connection switches SW5 and SW6 connected between the pair of detection output nodes N3 and N4 and the gates of the plurality of PMOS transistors MP1 and MP2, and MP3 and MP4 of the stacked PMOS circuit.

The control switch circuit directly connects or cross-connects the bit line BL and the bit line bar BLB of the bit line pair BL and BLB to the first and second nodes N1 and N2, in response to a precharge signal PRE and an amplification signal AMP, respectively. The control switch circuit includes two selection switch circuits.

Among the two selection switch circuits, the first selection switch circuit includes a first switch SW1, which is connected between the bit line BL and the first node N1 on one side of the first NMOS transistor MN1 and turned on in response to the precharge signal PRE, and a second switch SW2, which is connected between the bit line bar BLB and the first node N1 and turned on in response to the amplification signal AMP. The second selection switch circuit includes a first switch SW3, which is connected between the bit line bar BLB and the second node N2 on one side of the second NMOS transistor MN2 and turned on in response to the precharge signal PRE, and a second switch SW4, which is connected between the bit line BL and the second node N2 and turned on in response to the amplification signal AMP.

Accordingly, the first selection switch circuit connects the bit line BL to the first node N1 in response to the precharge signal PRE and connects the bit line bar BLB to the first node N1 in response to the amplification signal AMP. In addition, the second selection switch circuit connects the bit line bar BLB to the second node N2 in response to the precharge signal PRE and connects the bit line BL to the second node N2 in response to the amplification signal AMP.

The first NMOS transistor MN1 is connected between the first node N1 and the first detection output node N3 of the detection output node pair N3 and N4, and the second NMOS transistor MN2 is connected between the second node N2 and the second detection output node N4. In addition, a clamp voltage V_{Clamp} is commonly applied to the gates of the first and second NMOS transistors MN1 and MN2. Since the same clamp voltage V_{Clamp} is applied to the gates of the first and second NMOS transistors MN1 and MN2, the first and second NMOS transistors MN1 and MN2 allow current to flow with essentially the same driving capability.

Meanwhile, the stacked PMOS circuit may include a first stack circuit connected between the power supply voltage V_{DD} and the first detection output node N3, and a second stack circuit connected between the power supply voltage V_{DD} and the second detection output node N4. The first stack circuit may be configured with a plurality of first PMOS transistors MP1 and MP2 connected in series between the power supply voltage V_{DD} and the first detection output node N3, and the second stack circuit may be configured with a plurality of second PMOS transistors MP3 and MP4 connected in series between the power supply voltage V_{DD} and the second detection output node N4. Although, in the illustrated example, each of the first and second stack circuits is composed of two PMOS transistors MP1 and MP2, and MP3 and MP4, respectively, the number of PMOS transistors stacked and connected in series in each of the first and second stack circuits may be adjusted.

Meanwhile, among the two gate connection switches SW5 and SW6, the first gate connection switch SW5 connects the first detection output node N3 to the gates of the plurality of first PMOS transistors MP1 and MP2 in response to a precharge signal PRE, and the second gate connection switch SW6 connects the second detection output node N4 to the gates of the plurality of second PMOS transistors MP3 and MP4 in response to the precharge signal PRE. Accordingly, the two gate connection switches SW5 and SW6 electrically connect drains and the gates of the plurality of first PMOS transistors MP1 and MP2 and the plurality of second PMOS transistors MP3 and MP4 during the precharge phase PH1 in which the precharge signal is activated, thereby providing a diode connection structure.

The first capacitor C1, which is connected between the gates of the plurality of first PMOS transistors MP1 and MP2 of the first stack circuit and the gates of the plurality of second PMOS transistors MP3 and MP4 of the second stack circuit, receives at its two terminals, during the precharge phase PH1, the signals applied to the gates of the plurality of first PMOS transistors MP1 and MP2 and the plurality of second PMOS transistors MP3 and MP4 through the first gate connection switch SW5 and the second gate connection switch SW6, that is, the detection signal pair SCO and SCOB output from the detection output node pair N3 and N4, and stores a voltage corresponding to a voltage difference between the detection signal pair SCO and SCOB.

After the precharge phase PH1, when the precharge signal PRE is deactivated in the amplification phase PH2 and the two gate connection switches SW5 and SW6 are turned off, the stored voltage is applied to the gates of the plurality of first PMOS transistors MP1 and MP2 of the first stack circuit and the gates of the plurality of second PMOS transistors MP3 and MP4 of the second stack circuit.

The configuration in which the first and second stack circuits of the stacked PMOS circuit include respective pluralities of PMOS transistors MP1 and MP2, and MP3 and MP4 connected in series, and in which the two gate connection switches SW5 and SW6 cause the plurality of first PMOS transistors MP1 and MP2 and the plurality of second PMOS transistors MP3 and MP4 to have a diode connection structure during the precharge phase PH1, is intended to increase the sensing margin by increasing the output resistance at the first and second detection output nodes N3 and N4.

The first capacitor C1 is connected between the gates of the plurality of first PMOS transistors MP1 and MP2 of the first stack circuit and the gates of the plurality of second PMOS transistors MP3 and MP4 of the second stack circuit, in order to remove an offset that occurs between the plurality of first PMOS transistors MP1 and MP2 and the plurality of second PMOS transistors MP3 and MP4.

The detection signal pair SCO and SCOB output from the detection output node pair N3 and N4 of the detection circuit 41 is applied to the amplification input node pair N7 and N8, which are the two input nodes of the detection amplifier circuit 43, through two offset-canceling switches SW7 and SW8. The two offset-canceling switches SW7 and SW8 are turned on in response to an offset-canceling signal OC, thereby electrically connecting the detection output node pair N3 and N4, which are the output nodes of the detection circuit 41, to the amplification input node pair N7 and N8, which are the input nodes of the detection amplifier circuit 43, respectively. The two offset-canceling switches SW7 and SW8 may also be regarded as components included in the detection circuit 41.

The detection amplifier circuit 43 includes two stacked inverter circuits 51 and 53 having dual-inputs, and two latch switches SW9 and SW10 that cross-connect the inputs and outputs of the two stacked inverter circuits 51 and 53 to form a latch structure.

The first stacked inverter circuit 51 among the two stacked inverter circuits 51 and 53 senses and inverts the detection signal SCO applied to the first amplification input node N7 of the amplification input node pair N7 and N8, and outputs the inverted response signal SAOB, which is one of the response signal pair SAO and SAOB that serve as the output signals of the detection amplifier circuit 43, to the first amplification output node N11. In addition, the first stacked inverter circuit 51 senses and inverts the inverted detection signal SCOB applied to the second amplification input node N8, and outputs the response signal SAO to the second amplification output node N12.

The first and second stacked inverter circuits 51 and 53 each have a structure in which two inverters are stacked and distinguished into an internal inverter and an external inverter. A second capacitor C2 and a third capacitor C3 are respectively connected between the first and second amplification input nodes N7 and N8, which are the input terminals of the external inverters, and the first and second internal input nodes N9 and N10, which are the input terminals of the internal inverters. In addition, a first equalization transistor MN7 and a second equalization transistor MN8 are respectively connected between the first and second internal input nodes N9 and N10 and the first and second amplification output nodes N11 and N12, which are the output nodes of the first and second stacked inverter circuits 51 and 53.

The two inverters stacked in the first stacked inverter circuit 51 are configured with two PMOS transistors MP5 and MP6 and two NMOS transistors MN3 and MN4 that are connected in series between the power supply voltage V_{DD} and the ground voltage V_{SS}. The two PMOS transistors MP5 and MP6 are connected in series between the power supply voltage V_{DD} and the first amplification output node N11, and the two NMOS transistors MN3 and MN4 are connected in series between the first amplification output node N11 and the ground voltage V_{SS}. The gates of the PMOS transistor MP6 and the NMOS transistor MN4, which form the internal inverter, are commonly connected to the first internal input node N9, and the gates of the PMOS transistor MP5 and the NMOS transistor MN3, which form the external inverter, are commonly connected to the first amplification input node N7.

In addition, the two inverters stacked in the second stacked inverter circuit 53 are also configured with two PMOS transistors MP7 and MP8 and two NMOS transistors MN5 and MN6 that are connected in series between the power supply voltage V_{DD} and the ground voltage V_{SS}. The two PMOS transistors MP7 and MP8 are connected in series between the power supply voltage V_{DD} and the second amplification output node N12, and the two NMOS transistors MN5 and MN6 are connected in series between the second amplification output node N12 and the ground voltage V_{SS}. The gates of the PMOS transistor MP8 and the NMOS transistor MN6, which form the internal inverter, are connected to the second internal input node N10, and the gates of the PMOS transistor MP7 and the NMOS transistor MN5, which form the external inverter, are commonly connected to the second amplification input node N8.

The PMOS transistors MP6 and MP8 and the NMOS transistors MN4 and MN6 that form the internal inverters in the first and second stacked inverter circuits 51 and 53 may be referred to as internal PMOS transistors and internal NMOS transistors, and the PMOS transistors MP5 and MP7 and the NMOS transistors MN3 and MN5 that form the external inverters may be referred to as external PMOS transistors and external NMOS transistors.

Meanwhile, among the two latch switches SW9 and SW10, the first latch switch SW9 connects the first internal input node N9, which is the input node of the internal inverter of the first stacked inverter circuit 51, to the second amplification output node N12, which is the output node of the second stacked inverter circuit 53, in response to a latch signal LAT. In addition, the second latch switch SW10 connects the second internal input node N10, which is the input node of the internal inverter of the second stacked inverter circuit 53, to the first amplification output node N11, which is the output node of the first stacked inverter circuit 51, in response to the latch signal LAT.

In the detection amplifier circuit 43, the fact that the first and second stacked inverter circuits 51 and 53 include the second and third capacitors C2 and C3 and the first and second equalization transistors MN7 and MN8 is because this configuration allows a signal to be input to the internal inverter in a coupled manner while removing offsets caused by variations among the transistors MN3 and MN4, MN5 and MN6, MP5 and MP6, and MP7 and MP8 constituting the two inverters, thereby improving the inverter and amplification gain.

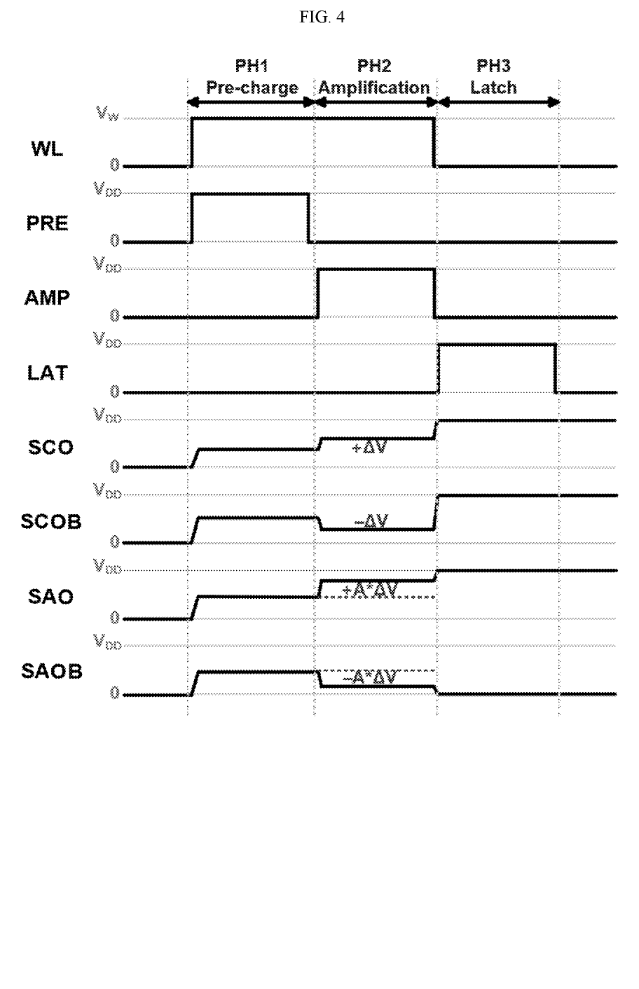

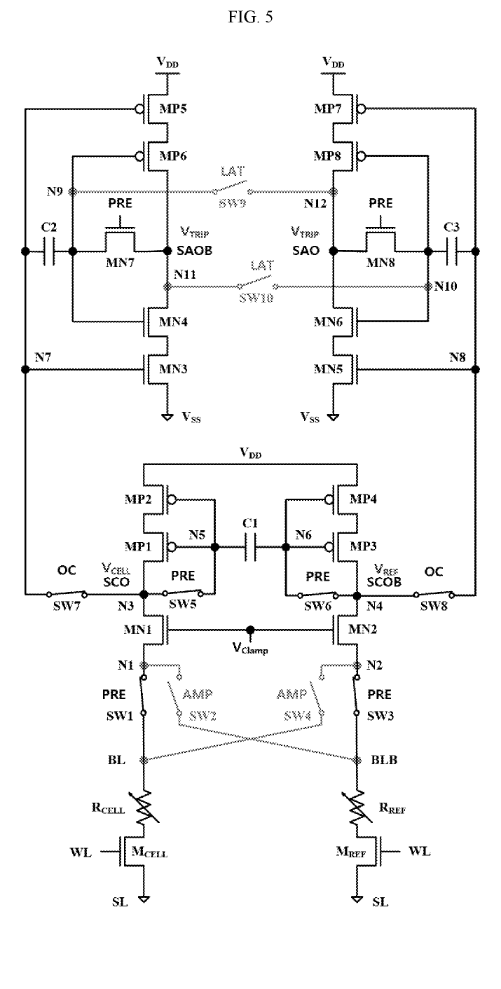

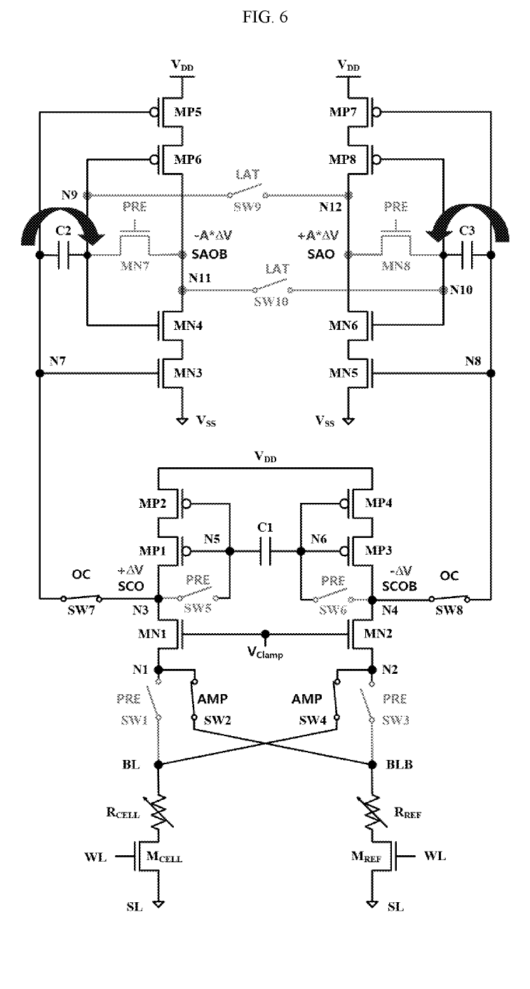

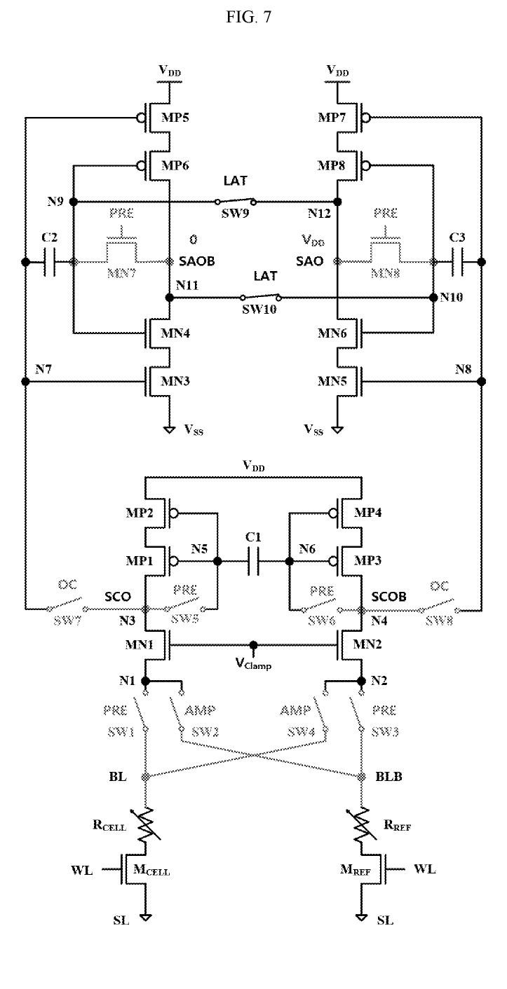

FIG. 4 is a timing diagram for explaining the operation of the current offset detection amplifier circuit of FIG. 3, FIG. 5 is a diagram for explaining a precharge operation of the current offset detection amplifier circuit of FIG. 3, and FIG. 6 is a diagram for explaining an amplification operation of the current offset detection amplifier circuit of FIG. 3. In addition, FIG. 7 is a diagram for explaining a latch operation of the current offset detection amplifier circuit of FIG. 3.

In FIGS. 5 to 7, the lines shown in gray indicate paths that are deactivated.

Referring to FIG. 4, the operation of the current offset detection amplifier circuit according to an embodiment can be divided into a precharge phase PH1, an amplification phase PH2, and a latch phase PH3.

Referring to FIGS. 4 and 5, in the precharge phase, the word line WL selected by the word line driver 20 is first activated, and the precharge signal PRE and the offset-canceling signal OC are also activated. For example, the word line WL may transition from the ground voltage V_{SS} to the word line voltage V_{W} level to become activated, and the precharge signal PRE and the offset-canceling signal OC may transition from the ground voltage V_{SS} to the supply voltage V_{DD} level to become activated. During this time, the amplification signal AMP and the latch signal LAT remain deactivated and, for example, may be held at the ground voltage V_{SS} level.

When a word line WL is activated, a plurality of cells connected to the activated word line WL are selected. The bit line selector 30 then selects two bit lines of a cell pair among the plurality of cells connected to the activated word line WL as the bit line pair BL and BLB, and connects them to the current offset detection amplifier circuit 40. Although the bit line selector 30 may select a plurality of cell pairs and connect a plurality of bit line pairs BL and BLB to the current offset detection amplifier circuit 40, for convenience, the following description assumes that only one bit line pair BL and BLB is connected to the current offset detection amplifier circuit 40.

When the bit line pair BL and BLB of the selected cell pair is connected to the detection circuit 41 of the current offset detection amplifier circuit 40, the control switch circuit in the detection circuit 41 responds to the activated precharge signal PRE and connects the bit line BL of the bit line pair BL and BLB to the first node N1, and the bit line bar BLB to the second node N2. The two NMOS transistors MN1 and MN2 remain turned on at all times due to the clamp voltage V_{Clamp} being commonly applied to their gates. Accordingly, a current path is formed from the power supply voltage V_{DD} through the stack PMOS circuit and the two NMOS transistors MN1 and MN2 to the two cells of the selected cell pair. At this time, the plurality of first PMOS transistors MP1 and MP2 stacked in the first stack circuit and the plurality of second PMOS transistors MP3 and MP4 stacked in the second stack circuit have a diode connection structure by the two gate connection switches SW5 and SW6 turned on in response to the precharge signal PRE.

Accordingly, the detection signal SCO output from the first detection output node N3 connected to the bit line BL has a cell voltage V_{CELL} according to the current flowing through the cell resistor R_{CELL} of the detection cell connected to the bit line BL and the current flowing through the first stack circuit. In addition, the inverted detection signal SCOB output from the second detection output node N4 connected to the bit line bar BLB has a reference voltage V_{REF} according to the current flowing through the cell resistor R_{REF} of the reference cell connected to the bit line bar BLB and the first stack circuit.

At this time, in the PUF device, the detection cell and the reference cell have the same state, that is, the same stored data. Therefore, in the precharge phase, as illustrated in FIG. 4, the cell voltage V_{CELL} of the detection signal SCO and the reference voltage V_{REF} of the inverted detection signal SCOB are obtained so as to have a voltage difference according to the voltage difference due to the deviation in the manufacturing process of the detection cell and the reference cell and the offset voltage difference due to the deviation in the manufacturing process of the plurality of PMOS transistors MP1 and MP2, and MP3 and MP4 of the first and second stack circuits, rather than being opposite voltages.

Here, as one example, it is assumed for explanation that, as shown in FIG. 4, the reference voltage V_{REF} of the inverted detection signal SCOB has a higher voltage level than the cell voltage V_{CELL} of the detection signal SCO.

Since the offset-canceling signal OC is activated, the two offset-canceling switches SW7 and SW8 apply the cell voltage V_{CELL} and the reference voltage V_{REF} of the detection signal pair SCO and SCOB output from the detection circuit 41 to the first and second amplification input nodes N7 and N8 of the detection amplifier circuit 43.

Meanwhile, in the detection amplifier circuit 43, the first and second equalization transistors MN7 and MN8 are turned on in response to the precharge signal PRE, thereby electrically connecting the first and second internal input nodes N9 and N10 to the first and second amplification output nodes N11 and N12, such that the inputs and outputs of the internal inverter of the first and second stacked inverter circuits 51 and 53 have the same trip voltage V_{TRIP} level. Here, the level of the trip voltage V_{TRIP} may be determined between the power supply voltage V_{DD} and the ground voltage V_{SS} according to characteristic differences between the two PMOS transistors MP5 and MP6, and MP7 and MP8 and the two NMOS transistors MN3 and MN4, and MN5 and MN6 in each of the first and second stacked inverter circuits 51 and 53. In other words, the voltage is determined according to the offset of the first and second stack inverter circuits 51 and 53.

Accordingly, the second capacitor C2 stores a voltage difference between the cell voltage V_{CELL} of the detection signal SCO and the trip voltage V_{TRIP}, and the third capacitor C3 stores a voltage difference between the reference voltage V_{REF} of the inverted detection signal SCOB and the trip voltage V_{TRIP}.

Referring to FIG. 4 and FIG. 6, in the amplification phase PH2, the selected word line WL remains activated, but the precharge signal PRE is deactivated. In addition, the amplification signal AMP becomes activated, and the offset-canceling signal OC also remains activated. However, the latch signal LAT remains deactivated.

Since the precharge signal PRE is deactivated and the amplification signal AMP is activated, the two first switches SW1 and SW3 of the control switch circuit in the detection circuit 41 are turned off, whereas the two second switches SW2 and SW4 are turned on. Accordingly, the bit line pair BL and BLB is cross-connected to the first and second nodes N1 and N2. In addition, as the two gate connection switches SW5 and SW6 are turned off, the plurality of PMOS transistors MP1 and MP2, and MP3 and MP4 of the stacked PMOS circuit no longer form a diode connection structure and operate in accordance with the voltage difference between the cell voltage V_{CELL} and the reference voltage V_{REF} stored in the first capacitor C1. In this case, the detection circuit 41 operates as a detection amplifier that detects and amplifies the voltage difference between the bit line pair BL and BLB.

When the cell resistance R_{CELL} of the detection cell is smaller than the cell resistance R_{REF} of the reference cell, the reference voltage V_{REF} has a higher voltage level than the cell voltage V_{CELL}. That is, in the first capacitor C1, the voltage level of one end of the first stacked circuit side becomes lower than the voltage level of the second stacked circuit side. Accordingly, in the amplification phase PH2, a greater amount of current flows through the first stacked circuit than through the second stacked circuit. In addition, since the two second switches SW2 and SW4 of the control switch circuit cross-connect the bit line pair BL and BLB to the first and second nodes N1 and N2, the current flowing through the first stacked circuit flows through the cell resistor R_{REF} of the reference cell, which has a relatively higher resistance value. As a result, the voltage level of the detection signal SCO rises from the cell voltage V_{CELL} by an amount ΔV. In contrast, since the current flowing through the second stacked circuit flows through the cell resistor R_{CELL} of the detection cell, which has a relatively lower resistance value, the voltage level of the inverted detection signal SCOB decreases from the reference voltage V_{REF} by an amount ΔV.

Here, in the first capacitor C1, during the precharge phase PH1, the cell resistor R_{CELL} of the detection cell already reflects not only the cell resistor R_{REF} of the reference cell, but also the offset caused by the plurality of PMOS transistors MP1 and MP2, and MP3 and MP4 of the stacked PMOS circuit. Accordingly, the voltage level of the detection signal pair SCO and SCOB is obtained as a voltage level in which the offset by the plurality of PMOS transistors MP1 and MP2, and MP3 and MP4 together with the cell resistor R_{REF} of the reference cell is reflected in the cell resistor R_{CELL} of the detection cell.

In particular, even when the cell voltage V_{CELL} and the reference voltage V_{REF} in the precharge phase PH1 are incorrectly detected and obtained due to the offset of the plurality of PMOS transistors MP1 and MP2, and MP3 and MP4, in which the cell resistor R_{CELL} of the detection cell is different from the resistance value of the cell resistor R_{REF} of the reference cell, since the voltage level of the detection signal pair SCO and SOCB drops at different rates due to the difference in the resistance value of the cell resistor R_{REF} of the reference cell, the cell resistor R_{CELL} of the detection cell connected to the crossed bit line pair BL and BLB in the amplification phase PH2 is ultimately detected and obtained correctly.

In addition, since the offset-canceling signal OC is still activated in the amplification phase PH2, the two offset-canceling switches SW7 and SW8 apply the detection signal pair SCO and SOCB to the first and second amplification input nodes N7 and N8 of the detection amplifier circuit 43.

Accordingly, in the first and second stacked inverter circuits 51 and 53 of the detection amplifier circuit 43, the external inverter controls the current flowing into the internal inverter in accordance with the voltage levels of the detection signal pair SCO and SOCB. Meanwhile, the second and third capacitors C2 and C3 apply the voltage variations of the detection signal pair SCO and SOCB applied to the first and second amplification input nodes N7 and N8, respectively, to the first and second internal input nodes N9 and N10, which are input terminals of the internal inverter, in a coupling manner. At this time, since the first and second equalization transistors MN7 and MN8, which connect the input and output of the internal inverter, are deactivated in response to the precharge signal PRE, the internal inverter inverts and amplifies the voltage variations of the detection signal pair SCO and SOCB applied in a coupling manner through the second and third capacitors C2 and C3, and outputs the response signal pair SAO and SAOB.

The first stacked inverter circuit 51 detects the voltage variation of the detection signal SCO, inverts and amplifies it, and outputs an inverted response signal SAOB that is lowered from the trip voltage V_{TRIP} by an amount A*ΔV. In addition, the second stacked inverter circuit 53 detects the voltage variation of the inverted detection signal SCOB, inverts and amplifies it, and outputs a response signal SAO that is raised from the trip voltage V_{TRIP} by an amount A*ΔV. Here, A denotes the amplification gain of the first and second stacked inverter circuits 51 and 53.

Here, since the second and third capacitors C2 and C3 already store voltages reflecting the offset resulting from variations of the transistors MP5 and MP6, MP7 and MP8, MN3 and MN4, MN5 and MN6 constituting the internal and external inverters, during the precharge phase PH1, erroneous detection due to the offset can be prevented.

Finally, in the latch phase PH3, the word line WL, the precharge signal PRE, the amplification signal AMP, and the offset-canceling signal OC are all deactivated, and the latch signal LAT is activated.

Since the word line WL, the precharge signal PRE, the amplification signal AMP, and the offset-canceling signal OC are all deactivated, the selected cell pair becomes deactivated, and the connection between the bit line pair BL and BLB and the current offset detection amplifier circuit 40 is cut off. In addition, the connection between the detection circuit 41 and the detection amplifier circuit 43 within the current offset detection amplifier circuit 40 is cut off. Accordingly, in the latch phase PH3, only the detection amplifier circuit 43 operates independently.

Since the first and second equalization transistors MN7 and MN8 in the detection amplifier circuit 43 remain deactivated, the first and second stacked inverter circuits 51 and 53 each operate as an inverter. In addition, since the first latch switch SW9, which connects the input terminal of the first stacked inverter circuit 51 to the output terminal of the second stacked inverter circuit 53, and the second latch switch SW10, which connects the input terminal of the second stacked inverter circuit 53 to the output terminal of the first stacked inverter circuit 51, are both turned on in response to the latch signal, the detection amplifier circuit 43 operates as a latch circuit. Therefore, in the latch phase PH3, the detection amplifier circuit 43 operating as a latch circuit further detects and amplifies the voltage difference between the response signal pair SAO and SAOB so that the response signal pair SAO and SAOB have the supply voltage V_{DD} level and the ground voltage V_{SS} level, respectively.

As a result, the current offset detection amplifier circuit 40 according to one embodiment has a two-stage structure including the detection circuit 41 and the detection amplifier circuit 43, and not only can remove offset using the first through third capacitors C1 to C3, but also can suppress the influence of leakage current transmitted from unselected cells or the parasitic resistance of the bit line, by transmitting signals in a coupling manner.

In the illustrated embodiment, respective configurations may have different functions and capabilities in addition to those described above, and may include additional configurations in addition to those described above. In addition, in an embodiment, each configuration may be implemented using one or more physically separated devices, or may be implemented by one or more processors or a combination of one or more processors and software, and may not be clearly distinguished in specific operations unlike the illustrated example.

In addition, the current offset detection amplifier circuit illustrated in FIG. 3 may be implemented in a logic circuit by hardware, firm ware, software, or a combination thereof or may be implemented using a general purpose or special purpose computer. The apparatus may be implemented using hardwired device, field programmable gate array (FPGA) or application specific integrated circuit (ASIC). Further, the apparatus may be implemented by a system on chip (SoC) including one or more processors and a controller.

In addition, the current offset detection amplifier circuit may be mounted in a computing device or server provided with a hardware element as a software, a hardware, or a combination thereof. The computing device or server may refer to various devices including all or some of a communication device for communicating with various devices and wired/wireless communication networks such as a communication modem, a memory which stores data for executing programs, and a microprocessor which executes programs to perform operations and commands.

The present invention has been described in detail through a representative embodiment, but those of ordinary skill in the art to which the art pertains will appreciate that various modifications and other equivalent embodiments are possible. Therefore, the true technical protection scope of the present invention should be defined by the claims.

What is claimed is:

1. A current offset detection amplifier circuit comprising:
a detection circuit configured to, in a precharge phase, detect and store a voltage difference corresponding to currents flowing through a pair of bit lines connected to two cells configured based on a resistive memory element and storing the same data, and to, in an amplification phase following the precharge phase, output a pair of detection signals having an amplified voltage difference according to currents flowing through a pair of bit lines cross-connected with the stored voltage difference; and
a detection amplifier circuit configured to, in the precharge phase, store a voltage level corresponding to the pair of detection signals output from the detection circuit, and to, in the amplification phase, detect and amplify variations in voltages of the pair of detection signals in a coupled manner, thereby outputting a pair of response signals.

2. The current offset detection amplifier circuit according to claim 1,
wherein the detection circuit comprises:
a control switch circuit configured to connect the pair of bit lines to first and second nodes during the precharge phase, and to cross-connect the pair of bit lines to the first and second nodes during the amplification phase;
first and second NMOS transistors connected between the first and second nodes and a pair of detection output nodes from which the pair of detection signals are output, gates of the first and second NMOS transistors being commonly applied with a clamp voltage;
a stacked PMOS circuit comprising first and second stack circuits, each stack circuit comprising a plurality of PMOS transistors connected in series between a power supply voltage and the pair of detection output nodes; and
a first capacitor connected between gates of the plurality of PMOS transistors in the first stack circuit and gates of the plurality of PMOS transistors in the second stack circuit.

3. The current offset detection amplifier circuit according to claim 2,
wherein the detection circuit further comprises:
a first gate connection switch configured to connect a first detection output node of the pair of detection output nodes to the gates of the plurality of PMOS transistors in the first stack circuit during the precharge phase; and
a second gate connection switch configured to connect a second detection output node of the pair of detection output nodes to the gates of the plurality of PMOS transistors in the second stack circuit during the precharge phase.

4. The current offset detection amplifier circuit according to claim 2,
wherein the control switch circuit comprises:
a first switch circuit configured to connect a bit line of the pair of bit lines to the first node during the precharge phase and to connect a bit line bar of the pair of bit lines to the first node during the amplification phase, and
a second switch circuit configured to connect the bit line bar to the second node during the precharge phase and to connect the bit line to the second node during the amplification phase.

5. The current offset detection amplifier circuit according to claim 1,
wherein the detection amplifier circuit comprises:
a first stacked inverter circuit configured to detect and amplify a voltage variation of a detection signal among the pair of detection signals and output an inverted response signal of the pair of response signals, and
a second stacked inverter circuit configured to detect and amplify a voltage variation of an inverted detection signal among the pair of detection signals and output a response signal of the pair of response signals.

6. The current offset detection amplifier circuit according to claim 5,
wherein the first stacked inverter circuit comprises:
a second capacitor connected between a first amplification input node to which the detection signal is applied and a first internal input node,
a first internal inverter including a first internal PMOS transistor and a first internal NMOS transistor connected in series with their gates commonly connected to the first internal input node, and
a first external inverter including a first external PMOS transistor and a first external NMOS transistor connected respectively between a supply voltage and the first internal PMOS transistor, and between the first internal NMOS transistor and a ground voltage, with their gates commonly connected to the first amplification input node.

7. The current offset detection amplifier circuit according to claim 6,
wherein the second stacked inverter circuit comprises:
a third capacitor connected between a second amplification input node to which the inverted detection signal is applied and a second internal input node,
a second internal inverter including a second internal PMOS transistor and a second internal NMOS transistor connected in series with their gates commonly connected to the second internal input node, and
a second external inverter including a second external PMOS transistor and a second external NMOS transistor connected respectively between a supply voltage and the second internal PMOS transistor, and between the second internal NMOS transistor and a ground voltage, with their gates commonly connected to the second amplification input node.

8. The current offset detection amplifier circuit according to claim 7,
wherein the detection amplifier circuit further comprises
a first equalization transistor configured to connect the first internal input node and a first amplification output node, from which the inverted response signal is output, during the precharge phase, and a second equalization transistor configured to connect the second internal input node and a second amplification output node, from which the response signal is output.

9. The current offset detection amplifier circuit according to claim 7,
wherein the detection amplifier circuit further comprises:
a first latch switch configured to connect the first internal input node and a second amplification output node, from which the response signal is output, during a latch phase following the amplification phase, and
a second latch switch configured to connect the second internal input node and a first amplification output node, from which the inverted response signal is output, during the latch phase.

10. The current offset detection amplifier circuit according to claim 7,
wherein the current offset detection amplifier circuit further comprises
two offset-canceling switches configured to connect, in the precharge phase and the amplification phase, a first and a second detection output node, from which the pair of detection signals is output from the detection circuit, to a first and a second amplification input node of the detection amplifier circuit, respectively.

11. The current offset detection amplifier circuit according to claim 1,
wherein the cells are implemented as STT-MRAM.

12. A PUF device comprising:
a cell array including a plurality of cells defined by a plurality of word lines, a plurality of bit lines, and a plurality of source lines, the cells being configured based on resistive memory elements;
a word line driver configured to select and activate at least one of the plurality of word lines;
a bit line selector configured to select two bit lines as a pair from among the plurality of bit lines;
a detection circuit configured to, when two cells storing the same data are selected by the activated word line and the selected bit line pair, detect and store a voltage difference corresponding to currents flowing through the two selected cells via the selected bit line pair during a precharge phase, and to output a pair of detection signals having an amplified voltage difference according to currents flowing through a bit line pair cross-connected with the stored voltage difference during an amplification phase following the precharge phase; and
a detection amplifier circuit configured to store voltage levels corresponding to the pair of detection signals output from the detection circuit during the precharge phase, and to detect and amplify voltage variations of the pair of detection signals in a coupling manner during the amplification phase, thereby outputting a pair of response signals.

13. The PUF device according to claim 12,
wherein the detection circuit comprises:
a control switch circuit configured to connect the pair of bit lines to first and second nodes during the precharge phase, and to cross-connect the pair of bit lines to the first and second nodes during the amplification phase;
first and second NMOS transistors connected between the first and second nodes and a pair of detection output nodes from which the pair of detection signals are output, gates of the first and second NMOS transistors being commonly applied with a clamp voltage;
a stacked PMOS circuit comprising first and second stack circuits, each stack circuit comprising a plurality of PMOS transistors connected in series between a power supply voltage and the pair of detection output nodes; and
a first capacitor connected between gates of the plurality of PMOS transistors in the first stack circuit and gates of the plurality of PMOS transistors in the second stack circuit.

14. The PUF device according to claim 13,
wherein the detection circuit further comprises:
a first gate connection switch configured to connect a first detection output node of the pair of detection output nodes to the gates of the plurality of PMOS transistors in the first stack circuit during the precharge phase; and
a second gate connection switch configured to connect a second detection output node of the pair of detection output nodes to the gates of the plurality of PMOS transistors in the second stack circuit during the precharge phase.

15. The PUF device according to claim 13,
wherein the control switch circuit comprises:
a first switch circuit configured to connect a bit line of the pair of bit lines to the first node during the precharge phase and to connect a bit line bar of the pair of bit lines to the first node during the amplification phase, and
a second switch circuit configured to connect the bit line bar to the second node during the precharge phase and to connect the bit line to the second node during the amplification phase.

16. The PUF device according to claim 12,
wherein the detection amplifier circuit comprises:
a first stacked inverter circuit configured to detect and amplify a voltage variation of a detection signal among the pair of detection signals and output an inverted response signal of the pair of response signals, and
a second stacked inverter circuit configured to detect and amplify a voltage variation of an inverted detection signal among the pair of detection signals and output a response signal of the pair of response signals.

17. The PUF device according to claim 16,
wherein the first stacked inverter circuit comprises:
a second capacitor connected between a first amplification input node to which the detection signal is applied and a first internal input node,
a first internal inverter including a first internal PMOS transistor and a first internal NMOS transistor connected in series with their gates commonly connected to the first internal input node, and
a first external inverter including a first external PMOS transistor and a first external NMOS transistor connected respectively between a supply voltage and the first internal PMOS transistor, and between the first internal NMOS transistor and a ground voltage, with their gates commonly connected to the first amplification input node.

18. The PUF device according to claim 17,
wherein the second stacked inverter circuit comprises:
a third capacitor connected between a second amplification input node to which the inverted detection signal is applied and a second internal input node,
a second internal inverter including a second internal PMOS transistor and a second internal NMOS transistor connected in series with their gates commonly connected to the second internal input node, and
a second external inverter including a second external PMOS transistor and a second external NMOS transistor connected respectively between a supply voltage and the second internal PMOS transistor, and between the second internal NMOS transistor and a ground voltage, with their gates commonly connected to the second amplification input node.

19. The PUF device according to claim 18,
wherein the detection amplifier circuit further comprises:
first and second equalization transistors configured to connect the first internal input node and a first amplification output node, from which the inverted response signal is output, during the precharge phase, and to connect the second internal input node and a second amplification output node, from which the response signal is output; and
first and second latch switches configured to connect the first internal input node and the second amplification output node, during a latch phase following the amplification phase, and to connect the second internal input node and the first amplification output node.

20. The PUF device according to claim 18,
wherein the detection circuit further comprises
two offset-canceling switches configured to connect, in the precharge phase and the amplification phase, a first and a second detection output node, from which the pair of detection signals is output from the detection circuit, to a first and a second amplification input node of the detection amplifier circuit, respectively.
